(19) United States
(12) Patent Application Publication
(10) Pub. No.: US 2025/0237537 A1
(43) Pub. Date: Jul. 24, 2025

(54) Adaptive compression of collection frames

(71) Applicant: SAGEMCOM ENERGY & TELECOM SAS, BOIS-COLOMBES (FR)

(72) Inventors: Oussama ABID, BOIS-COLOMBES (FR); Abbas SABRAOUI, BOIS-COLOMBES (FR); Ahmet Samed BASTURK, BOIS-COLOMBES (FR)

(21) Appl. No.: 18/986,159

(22) Filed: Dec. 18, 2024

(30) Foreign Application Priority Data
Dec. 18, 2023 (FR) FR2314409

(51) Int. Cl. G01F 15/063

(52) U.S. Cl. CPC G01F 15/063

(57) ABSTRACT

A measurement transmission method is implemented in a meter and includes the steps of detecting at least one period of constant consumption formed by successive time intervals during each of which the consumption is equal to a constant value, and producing and transmitting a collection frame containing the measurement data associated with the time intervals of the measurement period, by replacing, for each constant consumption period, the measurement data associated with the successive time intervals of said constant consumption period with compacted data including a first data enabling it to identify the time intervals of the constant consumption period and a second data containing the constant value.

The invention relates to the field of smart meters: water meters, gas, electricity, etc.

### BACKGROUND OF THE INVENTION

Modern water meters, also known as “smart water meters”, naturally include a measurement module for measuring the water consumption of a water installation, and it also includes a processor module and a communication module.

The processor module acquires the measurements and enables the water meter to perform a certain number of functions, and in particular to analyse various kinds of data, relating for example to the water consumption of the installation, to the billing of the customer, to the state of the water distribution network, or indeed to the operation of the water meter itself.

The communication module makes it possible to integrate the meter into a communication network, for example of the LPWAN type (for Low Power Wide Area Network or extended low consumption network), and to communicate with other entities of the network, and in particular with the water supplier's Information System (IS), possibly via a data concentrator, a gateway, or another meter (such as a neighbourhood smart water meter).

Each day, a water meter transmits to the IS at least one collection frame containing water consumption indexes of the installation to which the meter is connected.

The remote transmission function of consumption indexes is essential because it allows better water management. Water suppliers use it to bill customers, to monitor water consumption in order to detect water leaks, excessive use and potential problems. Water suppliers can also adjust water production and distribution in real time according to demand, which can help reduce waste and optimize resources.

Each day is therefore divided into time intervals.

Each collection frame, produced by the processor module and transmitted by the communication module, is for example similar to that shown in the table in Annex 1. The protocol used for the communication is for example the DLMS protocol or the M-bus protocol. The collection frame contains, for each time interval, measurement data (consumption index). It can be seen in this collection frame that each time interval has a duration of 5 minutes and that the measurement data is the cumulative index (in litres). In one day, there are (24 h*60 mins)/5 mins=288 time intervals. Each measurement data has a size of 4 bytes, such that the size of the collection frame is at least 288×4 bytes=1152 bytes. The size of the collection frame is generally even more important. Indeed, it is possible for example, that control fields are present to indicate the number of indexes, the start time of the first index and the interval in hours between the indexes. For the sake of simplicity, these control fields have been deliberately omitted.

The smaller the collection step (duration of a time interval), the better the water supplier is able to manage the network, effectively detect leaks and optimise water distribution. Indeed, a fine resolution of the data allows a better accuracy in the detection of anomalies and variations in consumption, which facilitates the implementation of measures to reduce water losses and improve network efficiency.

However, reducing the collection step automatically increases the size of the collection frames.

Yet, it is known that the various electronic components of the water meter are powered by one or more batteries positioned in the meter. It is therefore advisable to limit the electrical consumption of the electronic components of the water meter, to increase its lifespan. Wireless transmission of consumption data has a significant impact on the meter's energy consumption. It is important to limit the power consumption of the communication module in particular, which forces manufacturers to increase the duration of the time intervals of the collection frame to reduce its size and thus, lose resolution.

In addition, longer collection frames require more time to be transmitted, which increases the congestion of the communication network and the risk of losing frames (forcing the frames to be retransmitted, and consequently further increasing the congestion).

Thus, although a fine resolution of the collection step is very advantageous, it implies a large size of collection frames and negatively impacts the meter's power consumption and network congestion.

### Aim of the Invention

The invention aims is to provide a solution for reducing the size of the collection frames transmitted by a meter, without reducing the resolution of the transmitted measurements.

### SUMMARY OF THE INVENTION

In view of achieving this aim, a measurement transmission method is proposed, implemented in a processor module of a meter designed to measure a quantity consumed by an installation during successive measurement periods, comprising the steps, for each measurement period, of:
dividing said measurement period into time intervals;
associating a measurement data with each time interval, said measurement data being representative of a consumption by the installation of the quantity during said time interval;
detecting, in said measurement period, at least one period of constant consumption formed by successive time intervals during each of which the consumption is equal to a constant value;
producing and transmitting a collection frame containing the measurement data associated with the time intervals of the measurement period, by replacing, for each constant consumption period, the measurement data associated with the successive time intervals of said constant consumption period with compacted data comprising at least a first data making it possible to identify said successive time intervals of said constant consumption period and a second data containing the constant value corresponding to said constant consumption period.

Based on the usual water consumption of households, it was found that a “normal” day includes a number of periods of constant consumption. These periods generally correspond to times when water is not consumed, for example in the evening or during working hours. This may also correspond to small leak rates that are constant over time.

The existence of these periods of constant consumption can be observed for any quantity measured by any type of meter: gas, electricity, etc.

The measurement transmission method therefore consists in detecting these periods of constant consumption in each measurement period, and compacting in the collection frame the measurement data associated with the time intervals of said periods of constant consumption. A collection frame of reduced size is therefore obtained without reducing the 5 resolution of the transmitted data.

In addition, a measurement transmission method is proposed, such as described above, comprising the step of verifying, for each constant consumption period, that a size of the compacted data is less than a size of the measurement data associated with the successive time intervals of said constant consumption period, and of replacing the measurement data with the compacted data only if this is the case.

In addition, a measurement transmission method is proposed, such as described above, further comprising the step, for each measurement period, of defining an optimum duration of the time intervals, the optimum duration being the shortest duration that makes it possible to maintain a size of the collection frame less than or equal to a predefined maximum size, said measurement period then being divided into time intervals having for duration the optimum duration.

In addition, a measurement transmission method is proposed, such as described above, further comprising the step of allocating, to each measurement data, an equal size of data obtained from a maximum value of the measurement data over said measurement period.

In addition, a measurement transmission method is proposed, such as described above, in which, for each time interval, the measurement data is equal to the consumption by the installation of the quantity during said time interval.

In addition, a meter is proposed comprising a communication module and a processor module in which the measurement transmission method is implemented as previously described above, the communication module being arranged to transmit the collection frames to an entity external to the meter.

In addition, a meter as described above is proposed, the meter being a fluid meter.

In addition, a computer program is proposed, comprising instructions which cause the processor module of the meter as described above, to execute the steps of the measuring method such as described above.

In addition, a computer-readable recording medium is proposed, on which the above described computer program is stored.

The invention will be best understood in light of the following description of a particular non-limiting embodiment of the invention.

### BRIEF DESCRIPTION OF THE DRAWINGS

Reference will be made to the accompanying drawings, among which:

FIG. 1 shows a water meter, a distribution network and an installation supplied by said network;

FIG. 2 shows a graph comprising a curve of the daily water consumption of an apartment;

FIG. 3 shows the steps in a process of defining the optimum duration of time intervals;

FIG. 4 shows the steps in a process for calculating the size of a collection frame.

### DETAILED DESCRIPTION OF THE INVENTION

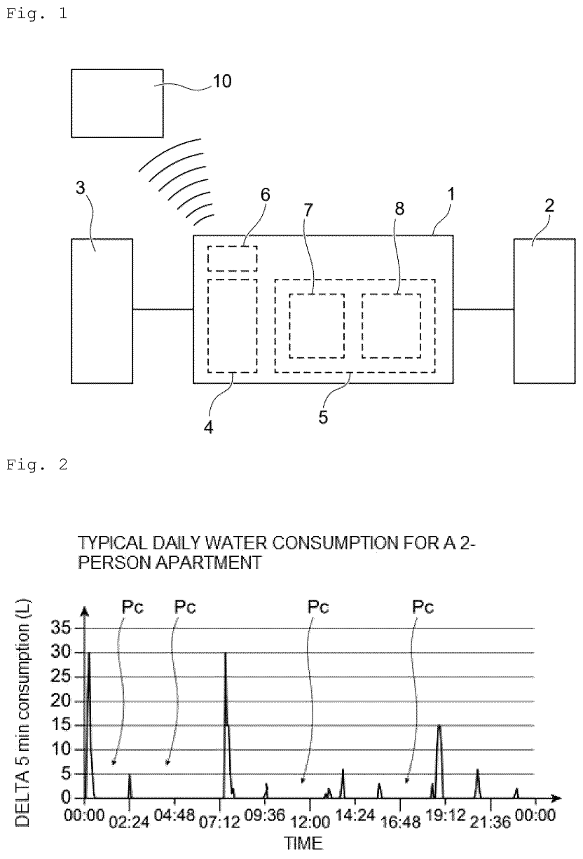

With reference to FIG. 1, a water meter 1 is used to measure the volume of water consumed by an installation 2. Water is supplied to the installation 2 by a water distribution network 3.

The meter 1 comprises a measurement module 4, a processor module 5 and a communication module 6.

The measurement module 4 comprises, for example, an ultrasonic measuring device that makes it possible to estimate the flow rate of water consumed and therefore, the volume of water consumed.

The processor module 5 is an electronic and software unit. The processor module 5 comprises at least one processing component 7, which is for example, a “general purpose” processor, a processor specialising in signal processing (or DSP, for Digital Signal Processor), a processor specialising in artificial intelligence algorithms (NPU-type, for Neural Processing Unit), a microcontroller, or a programmable logic circuit such as an FPGA (for Field Programmable Gate Arrays) or an ASIC (for Application Specific Integrated Circuit).

The processor module 5 also comprises one or more memories 8, connected to or integrated in the processing component 7. At least one of these memories 8 forms a computer-readable recording medium, on which is recorded at least one computer program comprising instructions that cause the processor module 5 to execute at least some of the steps of the measurement transmission method that will be described.

The processor module 5 implements a certain number of functions. Among these, the processor module 5 acquires the measurements made by the measurement module 4, processes and formats said measurements, and produces collection frames from these measurements. The collection frames are then transmitted to the IS 10 by the communication module 6.

The meter 1 therefore, measures the volume of water consumed by the installation 2 during successive measurement periods.

The measurement periods here each have a duration of one day, that is, 24 hours, and begin at 00:00 (00 h00) to end at 23:59 (23 h59).

After each measurement period, the processor module 5 produces a collection frame from the measurements made by the measurement module 4 during said measurement period.

According to data provided by the water agencies and ADEME (Agence de la transition écologique), which are French public institutions, the average consumption of drinking water in France for a household of four people is about 120 litres per day and per person.

Although the water consumption varies considerably according to the habits of each household and its equipment (number of people, sanitary facilities, household appliances, garden, etc.), the consumption profile systematically presents areas of non-consumption.

Non-consumption means two cases:
no consumption (i.e. zero flow);
stable consumption (for example, a small potential leak, which is stable over time).

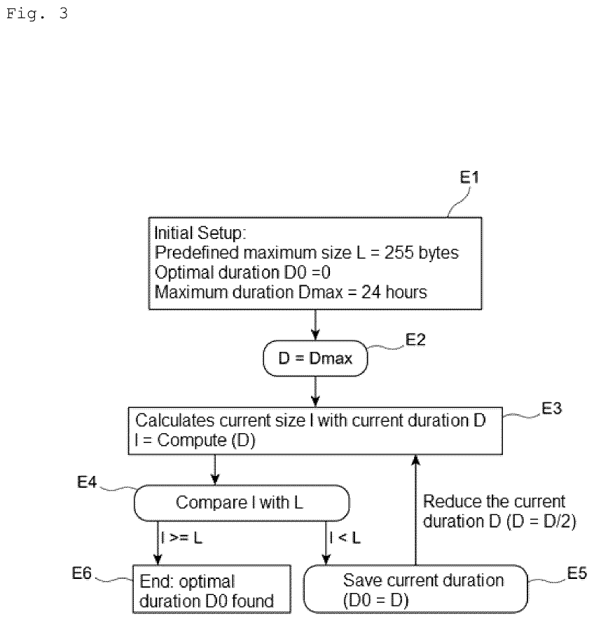

The typical daily consumption for a two-person apartment, shown in the graph of FIG. 2, shows that for at least 80% of the time, the variation in consumption is constant. This information is important because it is the entry point of the measurement transmission method described here.

This observation is not surprising, as households do not consume continuously. Continuous consumption is only observed in special cases (factory, water fountain, water leak).

For each measurement period, the processor module 5 first acquires all the measurements made by the measurement module 4 during said measurement period.

The processor module 5 divides each measurement period into time intervals.

The processor module 5 associates a measurement data to each time interval, said measurement data being representative of a water volume consumption by the installation 2 during said time interval.

The measurement data could be absolute cumulative indexes (as for the measurement frame in Appendix 1).

Here, however, for each time interval (except for the first), the measurement data is equal to the consumption by the installation of the quantity (volume of water) during said time interval. Thus, rather than sending absolute cumulative indexes, the processor module 5 calculates the index difference between two points in time, also called «delta index», that is, the index at the point in time «t» minus the index at the instant «t−1». In this way, the size allocated for each delta will be less than that allocated for a cumulative index (4 bytes for example for the cumulative index).

The processor module 5 then allocates, to each measurement data, the same size of data obtained from a maximum value of the measurement data over said measurement period.

The allocated data size is therefore calculated dynamically for each day according to the consumption deltas. By calculating all the deltas and selecting the maximum, it is possible to determine the size to be allocated for each delta, depending on this maximum value.

The processor module 5 uses the following formula:

$$data size = number of bits allocated per time interval = {rounded}_{sup} ( {log}_{2} ( \vert {Delta}_{max} \vert ) ) + 1$$

where Deltaₘₐₓ is the maximum value of the measurement data over said measurement period.

Thus, for example, if the maximum value of the measurement data over a measurement period is 30 litres for a 5 minutes step (time interval), then the processor module 5 allocates 6 bits to each measurement data (except for the one associated with the first time interval of the day, between 00:00 and 00:05). The 6 bits include a sign bit to cover the case of backflow («negative» consumption) which is taken into account by some water suppliers. The “+1” in the above formula allows the sign bit to be taken into account.

Thus, the size of the collection frame is reduced from 1152 bytes to 220 bytes, an 80% reduction in the size of the useful data.

The resulting collection frame obtained could then be similar to that in Appendix 2. The measurement data associated with the first time interval has a size of 4 bytes, because it contains the cumulative index of consumed water.

In contrast, the other measurement data has a size of 6 bits.

However, as just seen, based on the usual water consumption of households, it was observed that during 80% of the time, the difference in consumption is constant. These periods correspond to times when water is not generally used, such as in the evening or during working hours. This also corresponds to small leak rates that are constant over time.

It is therefore, particularly advantageous to compress these constant difference values in order to further reduce the size of the collection frame.

Thus, for each measurement period, the processor module 5 detects, in said measurement period, at least one period of constant consumption formed by successive time intervals (at least two) during each of which the consumption is equal to a constant value. FIG. 2 shows periods of constant consumption Pc.

For example, a day includes a period of constant consumption between 01:00 and 01:20 (that is, four successive time intervals), another period of constant consumption between 04:30 and 04:55 (that is, five successive time intervals), etc. For these two periods of constant consumption, the consumption may be zero (constant value=0 L), or non-zero in the case of a small constant leak. Constant consumption periods are detected dynamically and therefore, vary according to the measurement periods.

The processor module 5 then produces and transmits a collection frame containing the measurement data associated with the time intervals of the measurement period, by replacing, for each constant consumption period, the measurement data associated with the successive time intervals of said constant consumption period with compacted data comprising at least a first data making enabling to identify said successive time intervals of said constant consumption period and a second data containing the constant value corresponding to said constant consumption period.

Here, the compacted data includes, for each identified period of constant consumption:
two first data enabling to identify the successive time intervals of said period of constant consumption. These first data are the identifier of the first time interval of the constant consumption period (size of the data: 2 bytes), and the number of successive time intervals of the constant consumption period (data size: 1 byte);
a second data containing the constant value associated with the constant consumption period, that is, the constant index delta (size of the data: 2 bytes).

Thus, for each period of constant consumption, a 5 bytes encoded metadata is obtained.

Advantageously, the processor module 5 verifies, for each period of constant consumption, that a size of the compacted data is much smaller than a size of the measurement data associated with the successive time intervals of said period of constant consumption, and performs the replacement of the measurement data by the compacted data only if this is the case.

Thus, if the size of a metadata is greater than the area to be removed, the algorithm does not delete the area and keeps the area's measurement data.

When the SI 10 receives the collection frame, it begins by processing the metadata to obtain the original deltas. Advantageously, the processor module 5 defines an optimum duration of the time intervals. The optimum duration is the smallest duration that enables to keep a size of the collection frame less than or equal to a predefined maximum size. The processor module 5 then divides said measurement period into time intervals having for duration the optimum duration, and produces the collection frame using time intervals each having for duration the optimum duration.

Thus, depending on the measurement periods, the duration of the time intervals may vary. The shorter the time intervals, the higher the resolution of the collected measurements, but the larger the size of the collection frame.

The optimum duration is therefore, the smallest duration that enables to keep a size of the collection frame less than or equal to the predefined maximum size.

In the context where the maximum payload size of the measurement frame is limited, a compression algorithm is therefore, used to adjust the resolution of the measurements in order to maximize the number of transmitted indexes while remaining below this fixed limit.

The general idea is that the compression algorithm can iterate through the data to be compressed and vary the resolution of the measurements. The algorithm can then evaluate the number of indexes generated using different resolutions and select the one that maximizes the number of indexes all the while ensuring that the total payload size remains below the specified limit.

By intelligently adjusting the resolution of the measurements, the algorithm can find a compromise between the accuracy of the data and the size of the payload.

We now turn to the implementation of the invention by describing two processes: a process for defining the optimum duration of the time intervals, and a process for calculating the size of the collection frame. These two processes are presented separately to improve the understanding of the method.

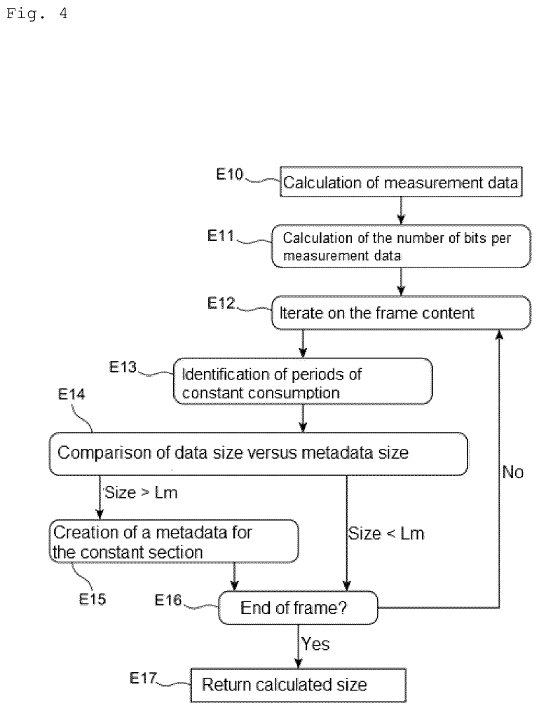

With reference to FIG. 3, we first present an example of an algorithm used to implement the process of defining the optimum duration of the time intervals.

This process uses the process of calculating the size of a collection frame, which will be described below.

The algorithm in FIG. 3 enables to define the optimum duration of each time interval for the transmission of data according to a predefined maximum size L of the collection frame, which is the size not to be exceeded.

For example, L=255 bytes.

The algorithm uses the variables:
Current duration D of the time intervals;
Current size 1 of the collection frame.

The process begins with a step consisting of defining the initial configuration: step E1. The initial configuration is defined with the following parameters.

The predefined maximum size is equal to L=255 bytes. The optimum duration D0 of each time interval is initialised to 0. The maximum duration Dmax of a time interval is 24 hours.

Then, the current duration D is initialised with the value Dmax:
D=Dmax (step E2).

The processor module 5 then calculates the current size 1 of the collection frame using the current duration D (step E3). The processor module 5 uses for this calculation the process of calculating the size of a collection frame which will be described below. Here, this function is called «Compute (D)».

The processor module 5 then compares the current size 1 of the collection frame with the predefined maximum size L (step E4).

If the current size 1 is less than the predefined maximum size L (here strictly less), the processor module 5 saves the current duration D as the optimum duration DO:
D0=D (step E5).

The processor module 5 then reduces the current duration D:

$$D = D / 2.$$

Then, the algorithm returns to step E3.

In step E4, if the current size 1 is greater than the predefined maximum size L (here greater than or equal to), the process ends (step E6). The optimum duration DO has been identified.

This algorithm can be implemented in the following manner:

```
int main( ) {
  int L = 255;
  int Pmin = 1; // Unit: minutes
  int Pmax = 24*60; // Unit: minutes
  int Po = 0;
  for (int P = Pmax; P >= Pmin; P /= 2) {
    int l = compute(P);
    if (l < L) {
      Po = P;
    } else {
      break;
    }
  }
  printf(“The optimum value of Po is: %d\n”, Po);
  return 0;
}
```

With reference to FIG. 4, an example of an algorithm used to implement the process of calculating the size of the collection frame («Compute (D)»). This process also enables it to produce the collection frame.

The operations described above are used: calculation of the measurement data, of the size allocated to each piece of measurement data, and of the metadata.

The process therefore, begins with the calculation of the measurement data, that is, the variations in consumption between the measurement intervals of the measurement period (step E10).

Then, the processor module 5 calculates the data size allocated to each measurement data, that is, the number of bits required to represent each index delta (step E11).

The processor module 5 then iterates on the content of the collection frame and scans each element of the collection frame to perform the compression operations (step E12).

The processor module 5 identifies the constant consumption periods (step E13).

The processor module 5 produces for each constant consumption period the compacted data and compares the measurement data size of each constant consumption period with the size of a metadata Lm (step E14).

If the size of the constant consumption period measurement data is greater (here strictly greater) than the size of a metadata, the processor module 5 uses said metadata to produce the collection frame (step E15).

The processor module 5 then verifies if the process has reached the end of the collection frame (step E16). If this is not the case, the method goes back to step E12.

If this is the case, the processor module returns the calculated size of the collection frame (step E17).

At step E14, if the measurement data size of the constant consumption period is less (here less than or equal to) than the size of a metadata, the processor module 5 does not use the metadata and keeps the constant consumption period measurement data in the collection frame. The method goes to step E16.

The invention therefore, enables collection data to be compressed in order to maintain a high measurement resolution, all the while reducing the amount of data to be transmitted.

This therefore, reduces the amount of data to be transmitted all the while maintaining sufficient resolution. The amount of useful information in a collection frame is maximised. The energy impact of collection frames in a smart meter is reduced.

The invention therefore, proposes a method for adaptively compressing the collection frame in order to reduce its size, all the while retaining the most important information on water consumption.

The invention proposes to study the water index data collected by the meter, calculate the index deltas and compress them using an appropriate compression algorithm.

The invention enables to maximize the amount of useful information in a given collection frame by adjusting, if necessary, the index measurement step.

Implementing the invention is very simple. Thanks to this “tailor-made” approach, it obtains a better conversion rate than standard compression methods.

Naturally, the invention is not limited to the embodiment described but comprises any variant entering into the field of the invention, such as defined by the claims.

The measurement transmission method can be implemented in any type of meter: fluid meter (water, gas, oil, etc.), electricity, etc. For electricity meters, reducing the electric consumption of said meters by implementing the method, is not necessarily very advantageous because they are generally powered by the electricity distribution network. On the other hand, as has been seen, the method also makes it possible, by reducing the size of the collection frames, to reduce the congestion of the communication network, which is very advantageous even for an electric meter.

Measurement periods need not necessarily be days.

The measurement data are not necessarily each equal to the installation's consumption of the quantity during a time interval. It could be a cumulative consumption. In this case, the compacted data may include data that identifies the time intervals of the constant consumption period, the constant consumption value corresponding to said constant consumption period, as well as the consumption value at the beginning of the first interval of the constant consumption period.

Annex 1
collection frame format

| | Cumulative | Index size |
|---|---|---|
| | index (L) | (bytes) |
| Index @ 00:00 | 12060 | 4 |
| Index @ 00:05 | 12064 | 4 |
| Index @ 00:10 | 12064 | 4 |
| . . . | | . . . |
| Index @ 23:55 | 12,184 | 4 |

Annex 2
collection frame format with delta index

| | Index | Size |
|---|---|---|
| | (L) | (bits) |
| Index @ 00:00 | 12060 | 4*8 |
| Delta Index @ 00:05 - Index @ | 4 | 6 |
| 00:00 | | |
| Delta Index @ 00:10 - Index @ | 30 | 6 |
| 00:05 | | |
| . . . | . . . | . . . |
| Delta Index @ 23:55 - Index @ | 2 | 6 |
| 23:50 | | |

1. A measurement transmission method, implemented in a processor module of a meter arranged to measure a quantity consumed by an installation during successive measurement periods, comprising the steps, for each measurement period, of:
dividing said measurement period into time intervals;
associating a measurement data with each time interval, said measurement data being representative of a consumption by the installation of the quantity during said time interval;
detecting, in said measurement period, at least one constant consumption period formed by successive time intervals during each of which the consumption is equal to a constant value;
producing and transmitting a collection frame containing the measurement data associated with the time intervals of the measurement period, by replacing, for each constant consumption period, the measurement data associated with the successive time intervals of said constant consumption period with compacted data comprising at least a first data making it possible to identify said successive time intervals of said constant consumption period and a second data containing the constant value corresponding to said constant consumption period.

2. The measurement transmission method according to claim 1, comprising the step of verifying, for each constant consumption period, that a size of the compacted data is smaller than a size of the measurement data associated with the successive time intervals of said constant consumption period, and of carrying out the replacement of the measurement data by the compacted data only if this is the case.

3. The measurement transmission method according to claim 1, further comprising the step, for each measurement period, of defining an optimum duration of the time intervals, the optimum duration being the shortest duration that makes it possible to maintain a size of the collection frame less than or equal to a predefined maximum size, said measurement period then being divided into time intervals having for duration the optimum duration.

4. The measurement transmission method according to claim 1, further comprising the step of allocating, to each measurement data, a same size of data obtained from a maximum value of the measurement data over said measurement period.

5. The measurement transmission method according to claim 1, wherein, for each time interval, the measurement data is equal to the consumption by the installation of the quantity during said time interval.

6. A meter comprising a communication module and a processor module wherein the measurement transmission method, according to claim 1, is implemented, the communication module being arranged to transmit the collection frames to an entity external to the meter.

7. The meter according to claim 6, the meter being a fluid meter.

8. (canceled)

9. A non-transitory computer-readable recording medium, on which a computer program is recorded, wherein the computer program comprises instructions which cause a processor module of a meter to execute the steps of the measurement transmission method according to claim 1.
